(19) United States
(12) Patent Application Publication
(10) Pub. No.: US 2013/0264721 A1
(43) Pub. Date: Oct. 10, 2013

(54) Electronic Module

(71) Applicants: Stefan Landau, Wehrheim (DE); Joachim Mahler, Regensburg (DE); Khalil Hosseini, Weihmichl (DE); Ivan Nikitin, Regensburg (DE); Thomas Wowra, Munich (DE); Lukas Ossowski, Waldetzenberg (DE)

(72) Inventors: Stefan Landau, Wehrheim (DE); Joachim Mahler, Regensburg (DE); Khalil Hosseini, Weihmichl (DE); Ivan Nikitin, Regensburg (DE); Thomas Wowra, Munich (DE); Lukas Ossowski, Waldetzenberg (DE)

(73) Assignee: INFINEON TECHNOLOGIES AG, Neubiberg (DE)

(21) Appl. No.: 13/440,478

(22) Filed: Apr. 5, 2012

(51) Int. Cl. H01L 23/48; H01L 21/56

(52) U.S. Cl. 257/777; 438/107; 257/E23.01; 257/E21.502

(57) ABSTRACT

The electronic module includes a first carrier and a first semiconductor chip arranged on the first carrier. A second semiconductor chip is arranged above the first semiconductor chip. A material layer adheres the second semiconductor chip to the first carrier and encapsulates the first semiconductor chip.

### TECHNICAL FIELD

The present invention relates to an electronic module and to a method for fabricating an electronic module.

### BACKGROUND

In the field of semiconductor chip packaging, very often the problem occurs that two or more chips have to be mounted on a carrier for fabricating a semiconductor chip package. The semiconductor chips can have different functions, sizes and properties. In particular, one of the semiconductor chips can be comprised of a power semiconductor chip and another one of the semiconductor chips can be comprised of a logic integrated circuit (IC) chip, both chips being part of, for example, a power converter or power supply circuit. The semiconductor chips can in principle be arranged side-by-side on a chip carrier which requires a special procedure and which leads to a package having a relatively large base area. There is, however, a general aim in the field of electronic devices to fabricate them with small overall size dimensions, in particular with a small base area.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic cross-sectional side view representation of an electronic module according to an embodiment;

FIG. 2 illustrates a schematic cross-sectional side view representation of an electronic module according to an embodiment;

FIG. 3 illustrates a schematic cross-sectional side view representation of an electronic module according to an embodiment;

FIG. 4 illustrates a schematic cross-sectional side view representation of an electronic module according to an embodiment;

FIG. 5 shows a flow diagram for illustrating a method for fabricating an electronic module according to an embodiment;

FIGS. 6A-6D illustrate schematic cross-sectional side view representations for illustrating a method for fabricating an electronic module according to an embodiment;

FIGS. 7A-7C illustrate schematic cross-sectional side view representations for illustrating a method for fabricating an electronic module according to an embodiment; and

FIGS. 8A-8B illustrate schematic cross-sectional side view representations for illustrating a method for fabricating an electronic module according to an embodiment.

### DETAILED DESCRIPTION OF ILLUSTRATIVE EMBODIMENTS

The aspects and embodiments are now described with reference to the drawings, wherein like reference numerals are generally utilized to refer to like elements throughout. In the following description, for purposes of explanation, numerous specific details are set forth in order to provide a thorough understanding of one or more aspects of the embodiments. It may be evident, however, to one skilled in the art that one or more aspects of the embodiments may be practiced with a lesser degree of the specific details. In other instances, known structures and elements are shown in schematic form in order to facilitate describing one or more aspects of the embodiments. It is to be understood that other embodiments may be utilized and structural or logical changes may be made without departing from the scope of the present invention. It should be noted further that the drawings are not to scale or not necessarily to scale.

In addition, while a particular feature or aspect of an embodiment may be disclosed with respect to only one of several implementations, such feature or aspect may be combined with one or more other features or aspects of the other implementations as may be desired and advantageous for any given or particular application. Furthermore, to the extent that the terms “include,” “have,” “with,” or other variants thereof are used in either the detailed description or the claims, such terms are intended to be inclusive in a manner similar to the term “comprise.” The terms “coupled” and “connected”, along with derivatives may be used. It should be understood that these terms may be used to indicate that two elements co-operate or interact with each other regardless whether they are in direct physical or electrical contact, or they are not in direct contact with each other. Also, the term “exemplary” is merely meant as an example, rather than the best or optimal. The following detailed description, therefore, is not to be taken in a limiting sense, and the scope of the present invention is defined by the appended claims.

The embodiments of an electronic module and a method for fabricating an electronic module may use various types of semiconductor chips or circuits incorporated in the semiconductor chips, among them logic integrated circuits, analog integrated circuits, mixed signal integrated circuits, sensor circuits, MEMS (Micro-Electro-Mechanical-Systems), power integrated circuits, chips with integrated passives, etc. The embodiments may also use semiconductor chips comprising transistors, power transistors, MOS transistor structures or vertical transistor structures like, for example, IGBT (Insulated Gate Bipolar Transistor) structures or, in general, transistor structures in which at least one electrical contact terminal is arranged on a first main face of the semiconductor chip and at least one other electrical contact terminal is arranged on a second main face of the semiconductor chip opposite to the first main face of the semiconductor chip.

In several embodiments layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole, such as, for example, laminating techniques as well as techniques in which layers are deposited in a sequential manner like, for example, sputtering, plating, molding, CVD, etc.

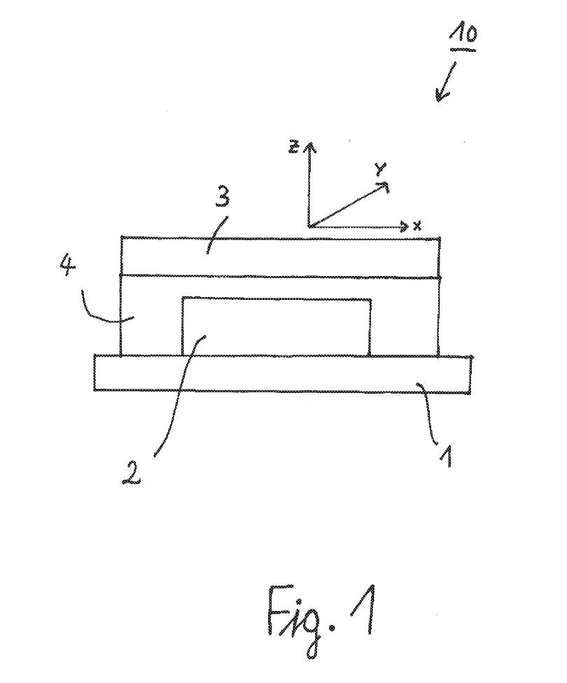

Referring to FIG. 1, there is shown a schematic cross-sectional side view representation of an electronic module according to an embodiment. The electronic module 10 of FIG. 1 comprises a first carrier 1, a first semiconductor chip 2 arranged on the first carrier 1, a second semiconductor chip 3 arranged above the first semiconductor chip 2, and a material layer 4 adhering the second semiconductor chip 3 to the first carrier 1 and encapsulating the first semiconductor chip 2.

According to an embodiment of the electronic module 10, the material layer 4 can be comprised of an adhesive foil or an adhesive tape. The adhesive foil can be, in principle, made of any sort of plastic material or polymer material. It can have a thickness in a range from 20 μm to 150 μm.

According to an embodiment of the electronic module 10, the material layer 4 can be comprised of an adhesive paste.

According to an embodiment of the electronic module 10, the second semiconductor chip 3 can be of greater size dimensions than the first semiconductor chip 2. In particular, as can be seen in FIG. 1, the second semiconductor chip 3 can be greater than the first semiconductor chip 2 along at least one direction designated as “x”. Moreover, the second semiconductor chip 3 can also be greater than the first semiconductor chip 2 in another horizontal direction perpendicular to the x-direction, namely a direction designated as “y.” In this case, the second semiconductor chip 3 can be arranged in such a way above the first semiconductor chip 2 that the second semiconductor chip 3 has outer side edges which extend laterally beyond respective side edges of the first semiconductor chip 2. In other words, the second semiconductor chip 3 can be arranged in such a way above the first semiconductor chip 2 that the second semiconductor chip 3 totally overlaps the first semiconductor chip 2 in all directions.

According to an embodiment of the electronic module 10, the second semiconductor chip 3 and the material layer 4 can have similar or equal lateral side dimensions which means that their respective side edges are laterally aligned with each other.

According to an embodiment of the electronic module 10, the material layer 4 can have greater lateral size dimensions than the second semiconductor chip 3.

According to an embodiment of the electronic module 10, the first semiconductor chip 2 can have a thickness less than 100 μm, in particular 10 μm to 100 μm, in particular 20 μm to 50 μm.

According to an embodiment of the electronic module 10, the second semiconductor chip 3 can have a thickness in a range from 40 μm to 800 μm.

According to an embodiment of the electronic module 10, the second semiconductor chip 3 can have a thickness greater than the thickness of the first semiconductor chip 2. In particular, the second semiconductor chip 2 can have a thickness which is at least two times greater than the thickness of the first semiconductor chip 2. It is to be understood that the thickness direction corresponds to the z direction as shown in FIG. 1.

According to an embodiment of the electronic module 10, the first and second semiconductor chips 2 and 3 can be electrically connected with each other.

According to an embodiment of the electronic module 10, the first semiconductor chip 3 can be comprised of one or more of a transistor chip, a MOS transistor chip, a vertical transistor chip, an IGBT transistor chip, and a power transistor chip. The second semiconductor chip 3 can be comprised of one or more of a processor chip, a controller chip, a logic circuit chip, and an integrated circuit chip.

According to an embodiment of the electronic module 10, the first semiconductor chip 2 can be comprised of one or more of a processor chip, a controller chip, a logic circuit chip, and an integrated circuit chip. The second semiconductor chip 3 can be comprised of one or more of a transistor chip, an MOS transistor chip, a vertical transistor chip, an IGBT transistor chip and a power transistor chip.

According to an embodiment of the electronic module 10, the material layer 4 can be electrically conductive. The material layer 4 can either comprise an isotropic electrical conductivity or an anisotropic electrical conductivity. It can also be the case that one or more of the first and second semiconductor chips 2 and 3 can comprise at least one electrical contact element, and the material layer 4 may electrically connect an electrical contact element of the first semiconductor chip 2 or of the second semiconductor chip 3 either with the first carrier 1 or with an electrical contact element of the respective other one of the first and second semi-conductor chips 2 and 3. A somewhat more detailed embodiment will be shown and explained later.

According to an embodiment of the electronic module 10, the material layer 4 can comprise electrically conductive particles embedded therein. The electrically conductive particles can be evenly distributed within the material layer 4 so that the material layer 4 may comprise an isotropic electrical conductivity. The electrically conductive particles can also be unevenly distributed within the material layer 4 so that the material layer 4 may comprise an anisotropic electrical conductivity.

According to an embodiment of the electronic module 10, a third semiconductor chip can be arranged above the first semiconductor chip 2 and laterally besides the second semi-conductor chip 3. The third semiconductor chip can be adhered to the first carrier 1 by the material layer 4. The second and third semiconductor chips can be dimensioned such that each one of them has smaller lateral size dimensions than the first semiconductor chip 2 but they can be arranged in such a way that they both laterally completely overlap the first semiconductor chip 1 in all directions. A somewhat more detailed embodiment will be shown and explained later.

According to an embodiment of the electronic module 10, the first semiconductor chip 1 may comprise a first electrical contact element on a first main face facing the second semiconductor chip 2. The electronic module 10 may further comprise an electrical connector and an electrical member connecting the first electrical contact element with the electrical connector. The electrical connector may be disposed in the same plane as the first carrier 1. Both, the first carrier 1 and the electrical connector may originate from one and the same leadframe which can be contiguous at the beginning of the fabrication process and which can then be separated into different electrical members during the fabrication process. The electrical member can be comprised on a metallic clip which can have a rigid form and shape and which can be connected with a plane lower surface of an upper part onto the first electrical contact element of the first semiconductor chip 2 and which can then extend downwards to the electrical connector and can be connected with a lower part with the electrical connector. A somewhat more detailed embodiment will be shown and explained later.

According to an embodiment of the electronic module 10, the electronic module 10 may further comprise a second carrier which can be arranged in the same plane as the first carrier 1, but which is electrically isolated from the first carrier 1. The first semiconductor chip 2 can be arranged on the first carrier 1 and on the second carrier. In particular, the first semiconductor chip 2 may comprise at least two electrical contact elements one of which is connected with the first carrier 1 and the other one of which is connected with the second carrier. It can also be that the second semiconductor chip 3 laterally extends above the second carrier and that the material layer 4 is attached to the second carrier. A somewhat more detailed embodiment will be shown and explained in the following.

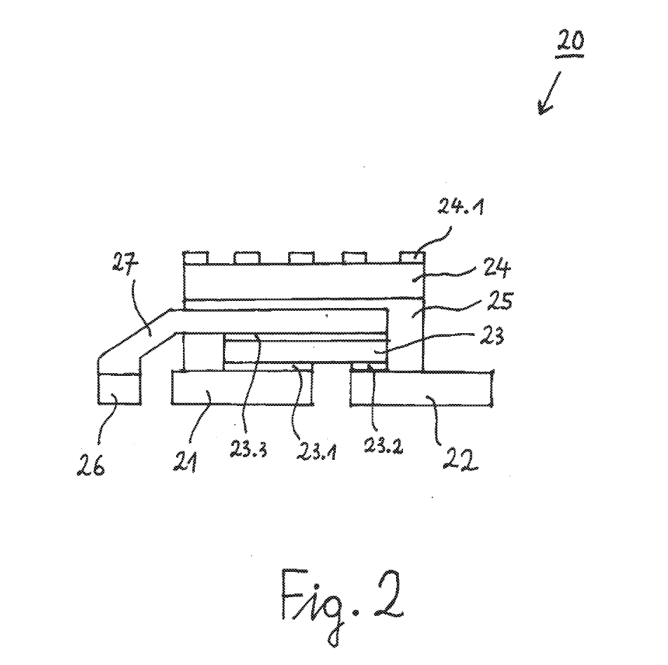

Referring to FIG. 2, there is shown a schematic cross-sectional side view representation of an electronic module according to an embodiment. The electronic module 20 of FIG. 2 comprises a first carrier 21, a second carrier 22, a first semiconductor chip 23 arranged on the first and second carriers 21 and 22, a second semiconductor chip 24 arranged above the first semiconductor chip 23, and a material layer 25 adhering the second semiconductor chip 24 to the first and second carriers 21 and 22 and encapsulating the first semiconductor chip 23.

The first semiconductor chip 23 can be comprised of one or more of a transistor chip, an MOS transistor chip, a vertical transistor chip, an IGBT transistor chip, and a power transistor chip. In any case the first semiconductor chip 23 may comprise a first electrical contact element 23.1 and a second electrical contact element 23.2 both arranged on a lower main surface of the first semiconductor chip 23, and a third electrical contact element 23.3 arranged on an upper main surface of the first semiconductor chip 23. The first electrical contact element 23.1 can be a source contact element, the second electrical contact element 23.2 can be a gate contact element, and the third electrical contact element 23.3 can be a drain contact element of the transistor chip. The first electrical contact element 23.1 can be attached to and electrically connected with the first carrier 21, and the second electrical contact element 23.2 can be attached to and electrically connected with the second carrier 22.

The electronic module 20 of FIG. 2 can further comprise an electrical connector 26 which can be arranged in one and the same plane as the first and second carriers 21 and 22. The first and second carriers 21 and 22 and the electrical connector 26 can originate from one and the same leadframe which can be contiguous at the beginning of the fabrication procedure and which can be successively separated into different electrical carriers and connectors electrically isolated from each other. The electrical connector 26 can be connected with the third electrical contact element 23.3 by means of an electrical member 27 which can have a rigid form and shape.

The first semiconductor chip 23 can have a thickness in a range from 10 μm to 100 μm, in particular from 20 μm to 50 μm.

The second semiconductor chip 24 can be comprised of one or more of a processor chip, a controller chip, an integrated circuit chip, and a logic integrated circuit chip. It can have a thickness in a range from 40 μm to 800 μm. The second semiconductor chip 24 can comprise electrical contact elements 24.1 which can be remote from the material layer 25. However, the electrical contact elements 24.1 can also be arranged in contact with or facing the material layer 25.

It is to be understood here that the different features and embodiments that were described above in connection with the electronic module 10 of FIG. 1 can also be applied for each one of the respective components of the electronic module 20 of FIG. 2.

Referring to FIG. 3, there is shown a schematic cross-sectional side view representation of an electronic module according to an embodiment. The electronic module 30 of FIG. 3 comprises a first carrier 31 and a second carrier 37, electrical connector elements 36, a first semiconductor chip 32 arranged on the carrier 31, a second semiconductor chip 34 arranged above the first semiconductor chip 32, and a material layer 33 adhering the second semiconductor chip 34 to the carrier 31 and encapsulating the first semiconductor chip 32.

The first semiconductor chip 32 can be comprised of one or more of a processor chip, a controller chip, an integrated circuit chip, and a logic integrated circuit chip. The first semiconductor chip 32 can furthermore comprise one or more electrical contact elements 32.1 arranged at a lower main face and each one of the electrical contact elements 32.1 connected by means of solder balls 35 to an electrical connector element 36. Each one of the electrical connector elements 36 and the first and second carriers 31 and 37 may originate from one and the same leadframe which was contiguous at the beginning of the fabrication process and which was separated into the first and second carriers 31 and 37 and the electrical connector elements 36.

The second semiconductor chip 34 can be comprised of one or more of a transistor chip, an MOS transistor chip, a vertical transistor chip, an IGBT transistor chip, and a power transistor chip. The second semiconductor chip 34 comprises a first electrical contact element 34.1 on a first lower main face, a second electrical contact element 34.2 arranged on a second upper main face, and a third electrical contact element 34.3 arranged on the second upper main face of the second semiconductor chip 34. The first electrical contact element 34.1 can be a drain contact element, the second electrical contact element 34.2 can be a source contact element, and the third electrical contact element 34.3 can be a gate contact element of the transistor chip.

The material layer 33 may encapsulate the first semiconductor chip 32 and it may serve at the same time as an underfill for the solder balls 35 which are arranged below the first semiconductor chip 32 and connect the electrical contact elements 32.1 with the first and second carriers 31 and 37 and the electrical connector elements 36, respectively.

It is to be understood here that the different features and embodiments that were described above in connection with the electronic module 10 of FIG. 1 can also be applied for each one of the respective components of the electronic module 30 of FIG. 3.

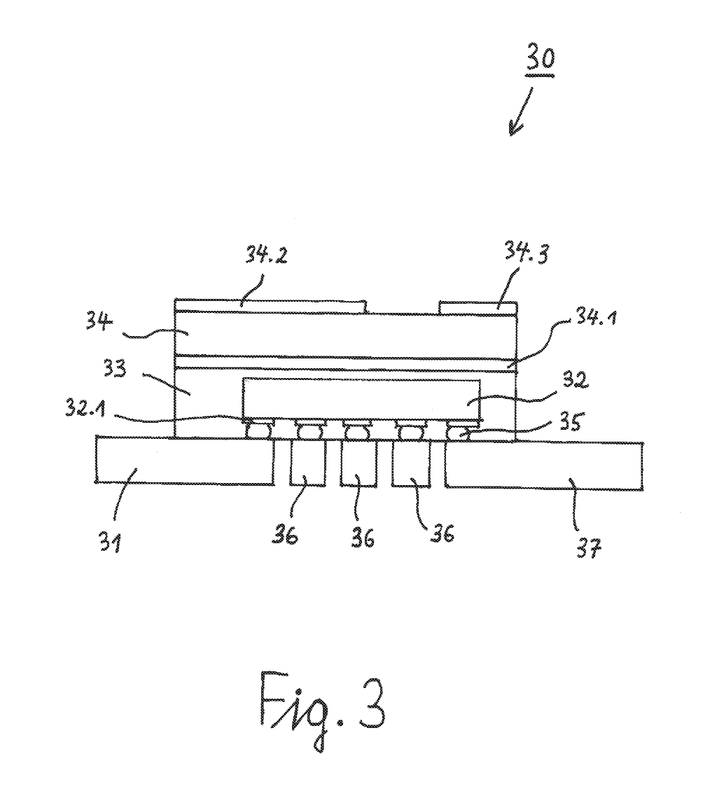

Referring to FIG. 4, there is shown a schematic cross-sectional side view representation of an electronic module according to an embodiment. The electronic module 40 of FIG. 4 may comprise a carrier 41, a first semiconductor chip 42 arranged on the carrier 41, a second semiconductor chip 43 arranged above the first semiconductor chip 42, a third semi-conductor chip 44 arranged above the first semiconductor chip 42, and a material layer 45 adhering the second and third semiconductor chips 43 and 44 to the carrier 41 and encapsulating the first semiconductor chip 42.

The first semiconductor chip 42 can be one or more of a transistor chip, an MOS transistor chip, a vertical transistor chip, an IGBT transistor chip, and a power transistor chip. The first semiconductor chip 42 comprises a first electrical contact element 42.1 arranged on a lower surface of the first semiconductor chip 42 and attached to and electrically connected with the carrier 41, a second electrical contact element 42.2 arranged on a second upper surface of the first semiconductor chip 42, and a third electrical contact element 42.3 arranged on the second upper surface of the semiconductor chip 42. The first electrical contact element 42.1 can be comprised of the drain contact element, the second electrical contact element 42.2 can be comprised of the source contact element, and the third electrical contact element 42.3 can be comprised of the gate contact element of the first semiconductor chip 42.

The second semiconductor chip 43 can be comprised of one or more of a transistor chip, an MOS transistor chip, a vertical transistor chip, an IGBT transistor chip, and a power transistor chip. The second semiconductor chip 43 comprises a first electrical contact element 43.1 on a first lower surface attached to an upper surface of the material layer 45, a second electrical contact element 43.2 arranged on a second upper surface, and a third electrical contact element 43.3 arranged on the second upper surface of the second semiconductor chip 43. The first electrical contact element 43.1 can be a drain contact element, the second electrical contact element 43.2 can be a source contact element, and the third electrical contact element 43.3 can be a gate contact element of the second semiconductor chip 43. The material layer 45 may comprise an anisotropic electrical conductivity which can be achieved by filling the material layer 45 with electrically conductive particles 45.1 in an unevenly distributed manner. As indicated in FIG. 4, the electrically conductive particles 45.1 can be filled into the material layer 45 in such a way that they are accumulated in a region of the material layer 45 between the second electrical contact element 42.2 of the first semiconductor chip 42 and the first electrical contact element 43.1 of the second semiconductor chip 43 so that an electrical connection between these electrical contact elements and thus between the first and second semiconductor chips 42 and 43 can be provided. It is also shown that the electrically conductive particles 45.1 can be filled into the material layer 45 in such a way that they are accumulated in a region of the material layer 45 between the third electrical contact element 42.3 of the first semiconductor chip 42 and a lower surface of the third semiconductor chip 44 so that there can also be provided an electrical connection between the first and third semiconductor chips 42 and 44.

The third semiconductor chip 44 can be comprised of one or more of a processor chip, a controller chip, an integrated circuit chip, and a logic integrated circuit chip. The third semiconductor chip 44 may comprise contact elements 44.1 on a surface remote from the material layer 45 or, alternatively, on a surface adjacent to the material layer 45.

It is to be understood here that the different features and embodiments that were described above in connection with the electronic module 10 of FIG. 1 can also be applied for each one of the respective components of the electronic module 40 of FIG. 4.

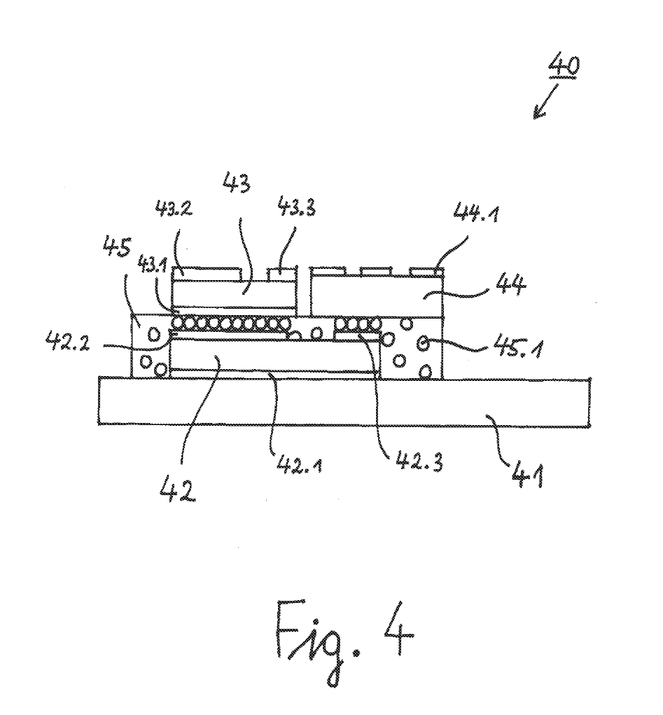

Referring to FIG. 5, there is shown a flow diagram for illustrating a method for fabricating an electronic module according to an embodiment. The method 50 comprises attaching a first semiconductor chip on a first carrier (51), attaching a material layer on a main face of a second semiconductor chip (52), and arranging the second semiconductor chip above the first semiconductor chip so that the material layer is attached to the first carrier and encapsulates the first semiconductor chip (53).

According to an embodiment of the method 50 of FIG. 5, the material layer may be comprised of an adhesive foil and attaching the material layer on a main face of a second semi-conductor chip may comprise laminating the adhesive foil on the main face of the second semiconductor chip.

According to an embodiment of the method 50 of FIG. 5, the material layer may be comprised of an adhesive paste, and attaching the material layer on a main face of a second semi-conductor chip may comprise applying the adhesive paste on the main face of the second semiconductor chip.

According to an embodiment of the method 50 of FIG. 5, the method 50 further comprises electrically connecting the first semiconductor chip with an electrical connector by use of an electrical member before applying the second semiconductor chip to the first semiconductor chip. The electrical connector may be disposed in the same plane as the first carrier and may origin from one and the same leadframe as the first carrier.

According to an embodiment of the method 50 of FIG. 5, the first semiconductor chip can be attached also on a second carrier which can be electrically isolated from the first carrier. The second carrier may be disposed in the same plane as the first carrier and it may originate from one and the same leadframe as the first carrier. The first semiconductor chip may comprise on one of its main surfaces a first electrical contact element and a second electrical contact element and the first electrical contact element may be attached to and electrically connected with the first carrier and the second electrical contact element may be attached to and electrically connected with the second carrier. The second semiconductor chip can be arranged in such a way above the first semiconductor chip that the material layer is also attached to the second carrier.

According to an embodiment of the method 50 of FIG. 5, a third semiconductor chip is arranged above the first semiconductor chip and besides the second semiconductor chip wherein the method may further comprise adhering the third semiconductor chip to the carrier by use of the material layer.

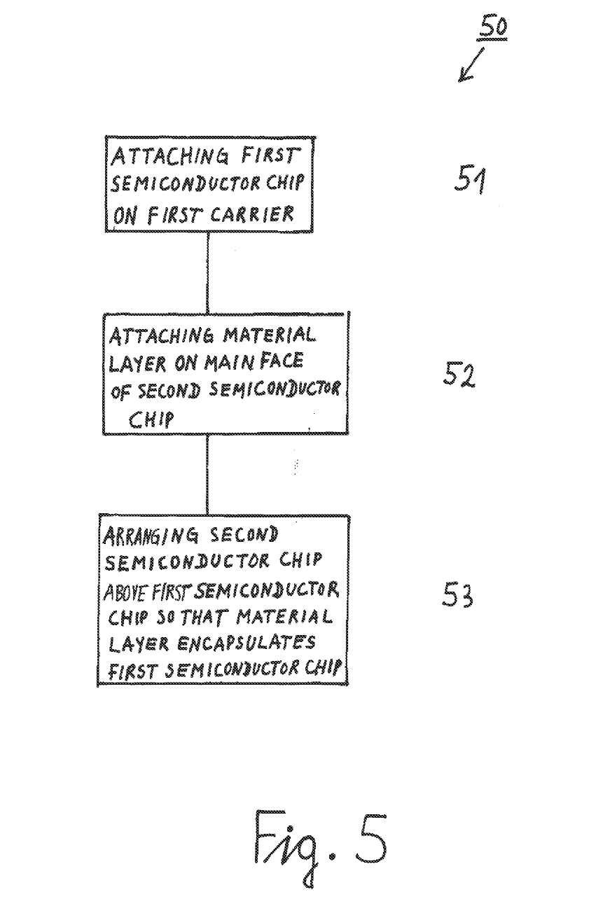

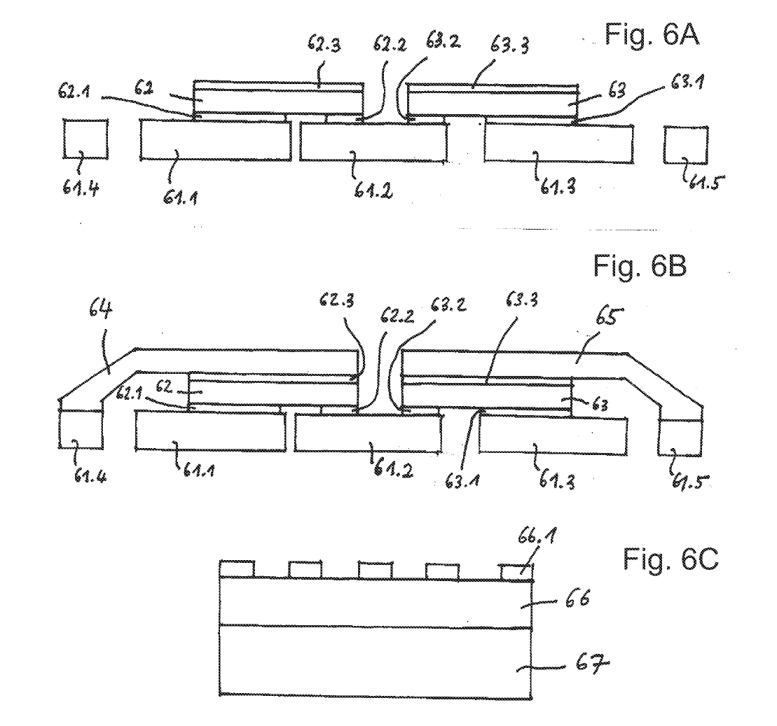

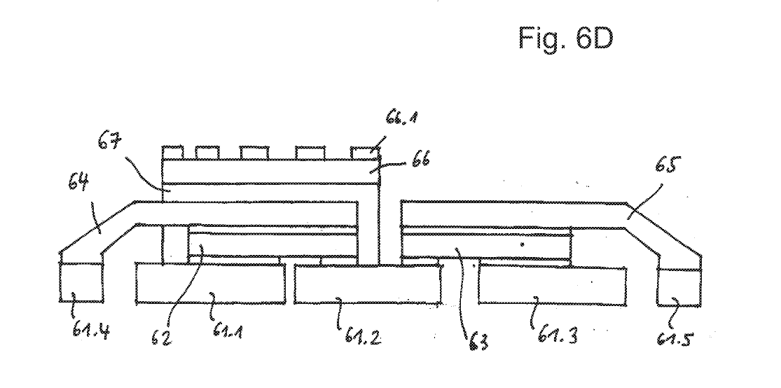

Referring to FIGS. 6A-6D, there are shown schematic cross-sectional side view representations to illustrate an exemplary method according to an embodiment. FIG. 6A shows a first carrier 61.1, a second carrier 61.2, a third carrier 61.3, a first electrical connector 61.4, and a second electrical connector 61.5, all of which may originate from one and the same leadframe 61 and which are going to be separated from each other during the fabrication process. A first power transistor chip 62 is attached on the first and second carriers 61.1 and 61.2, and a second power transistor chip 63 is attached on the second and third carriers 61.2 and 61.3. The first power transistor chip 62 comprises on a lower main surface thereof a source contact element 62.1 and a gate contact element 62.2, and the source contact element 62.1 is attached to and electrically connected with the first carrier 61.1, and the gate contact element 62.2 is attached to and electrically connected with the second carrier 61.2. The power transistor chip 62 further comprises on an upper main surface thereof a drain contact element 62.3. The second power transistor chip 63 comprises on a lower main surface thereof a source contact element 63.1 and a gate contact element 63.2, and the source contact element 63.1 is attached to and electrically connected with the third carrier 61.3, and the gate contact element 63.2 is attached to and electrically connected with the second carrier 61.2. The second power transistor chip 63 further comprises on an upper main surface thereof a drain contact element 63.3.

FIG. 6B shows the assembly after electrically connecting the first and second power transistor chips 62 and 63 to the first and second electrical connectors 61.4 and 61.5, respectively. A first electrical member 64 is utilized to make an electrical connection between the drain contact element 62.3 and the first electrical connector 61.4, and a second electrical member 65 is utilized to make an electrical contact between the drain contact element 63.3 with the second electrical connector 61.5. The first and second electrical members 64 and 65 can be made of metallic clips.

FIG. 6C shows a schematic cross-sectional side view representation of an assembly comprising a logic integrated circuit chip 66 having electrical contact elements 66.1. On a main surface of the logic integrated circuit chip 66, which is remote from the electrical contact element 66.1, an adhesive foil 67 is attached which can have a thickness in a range from 20 μm to 150 μm. The drawing is not necessarily to scale which means that the chip 66 can have in principle any desired thickness in a range from 40 μm to 800 μm.

FIG. 6D again shows the complete assembly in which the logic integrated circuit chip 66 is attached together with the adhesive foil 67 to the first power transistor chip 62 and the first and second carriers 61.1 and 61.2. The dimensions of the adhesive foil 67 can be such that the adhesive foil 67 encapsulates the first power transistor chip 62 on all sides.

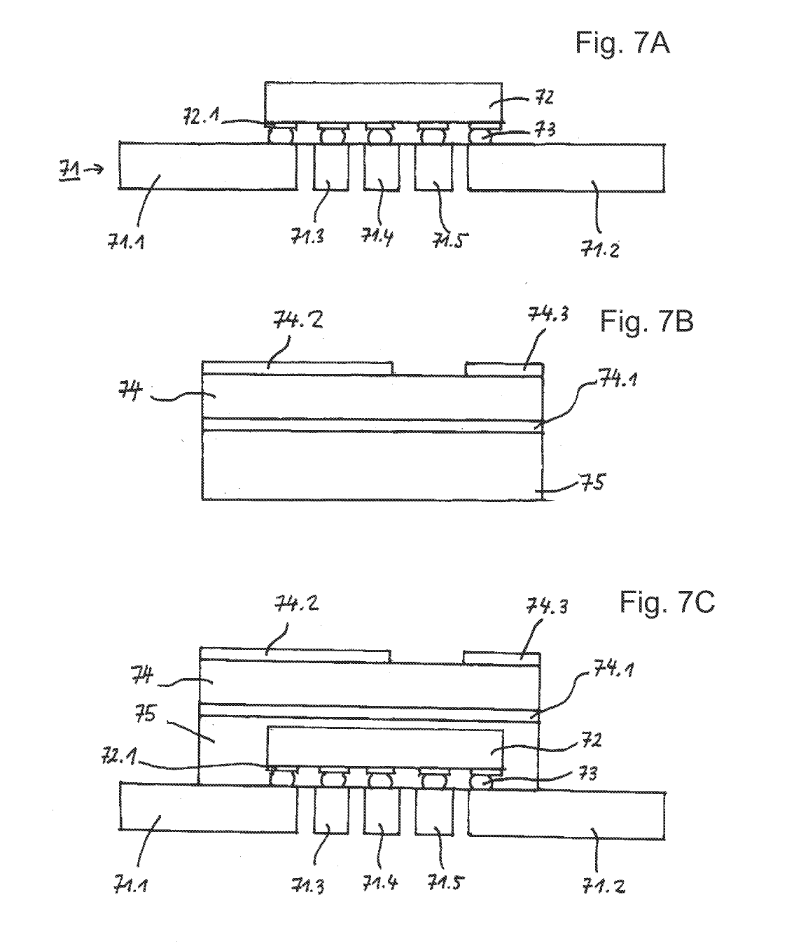

FIGS. 7A-7C show schematic cross-sectional side view representations to illustrate a method for fabricating an electronic module according to an embodiment. FIG. 7A shows an assembly comprising a first carrier 71.1, a second carrier 71.2, a first electrical connector 71.3, a second electrical connector 71.4, and a third electrical connector 71.5, all of which may origin from one and the same leadframe 71 and which can be separated from each other during the fabrication process. The assembly may further comprise a logic integrated circuit 72 which comprises electrical contact elements 72.1 at a lower main surface thereof. Each one of the electrical contact elements 72.1 is electrically connected with one of the first and second carriers 71.1 and 71.2 or one of the electrical connectors 71.3 to 71.5 by means of solder balls 73.

FIG. 7B shows an assembly comprising a power transistor chip 74 and an adhesive foil 75. The power transistor chip 74 comprises on a lower main surface thereof a drain contact element 74.1 and on an upper main surface thereof a source contact element 74.2 and a gate contact element 74.3. The adhesive foil 75 is attached to the lower main surface of the power transistor chip 74, i.e. to the drain contact element 74.1. The adhesive foil may comprise a thickness in a range from 20 μm to 150 μm. The drawing is not necessarily to scale which means that the power transistor chip can have in principle any desired thickness.

FIG. 7C shows the assembly after attaching the power transistor chip 74 together with the adhesive foil 75 to the logic integrated circuit chip 72, the first and second carriers 71.1 and 71.2 and the first to third electrical connectors 71.3 to 71.5. The dimensions of the adhesive foil 75 can be such that the adhesive foil 75 completely encapsulates the logic integrated circuit chip 72 from all sides.

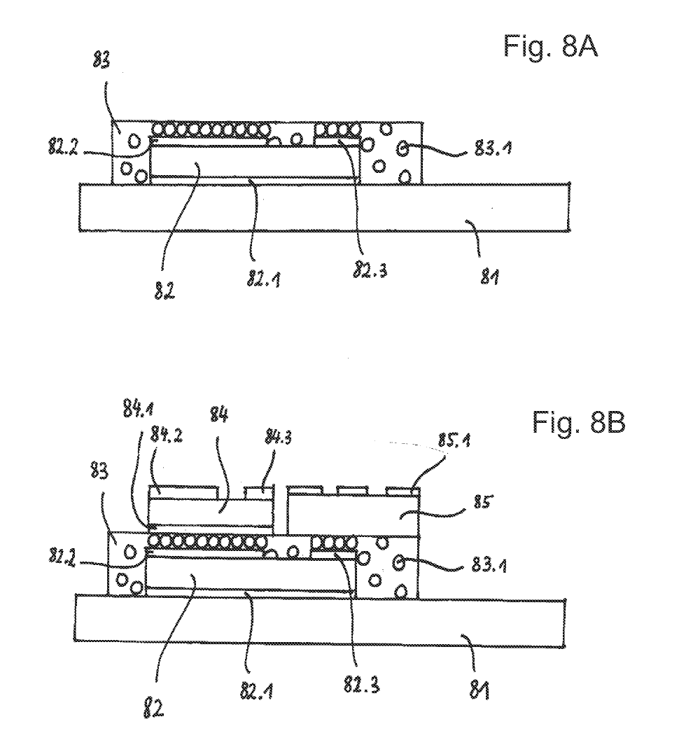

FIGS. 8A and 8B show schematically cross-sectional side view representations to illustrate a method for fabricating an electronic module according to an embodiment. FIG. 8A shows an assembly comprised of a carrier 81, a first power transistor chip 82, and an adhesive paste 83. The first power transistor chip 82 may comprise a drain contact element 82.1, a source contact element 82.2, and a gate contact element 82.3. The first power transistor chip 82 can be attached to the carrier 81 in such a way that the drain contact element 82.1 is attached to and electrically connected with a surface of the carrier 81. The adhesive paste 83 can be attached to the first power transistor chip in such a way that it completely encapsulates the first power transistor chip 82 on all sides. The adhesive paste 83 may comprise electrically conductive particles 83.1 which can be unevenly distributed within the adhesive paste 83 so that the adhesive paste 83 may comprise an anisotropic electrical conductivity.

FIG. 8B shows the assembly after attaching a second power transistor chip 84 and a logic integrated circuit chip 85 to an upper surface of the adhesive paste 83. The second power transistor chip 84 may comprise on a lower main surface thereof a drain contact element 84.1 and on an upper main surface thereof a source contact element 84.2 and a gate contact element 84.3. The second power transistor chip 84 can be attached to the adhesive paste 83 in such a way that the drain contact element 84.1 is attached to the upper surface of the adhesive paste 83 and makes electrical contact with an electrically conductive region of the adhesive paste 83. The electrically conductive region of the adhesive paste 83 is symbolized by a high accumulation of electrically conductive particles 83.1 in a region of the adhesive paste 83 between the source contact element 82.2 of the first power transistor chip 82 and the drain contact element 84.1 of the second power transistor chip 84. The logic integrated circuit chip 85 may comprise electrical contact elements 85.1 at an upper main surface remote from the adhesive past 83 and it may also comprise electrical contact elements on a lower main surface thereof (not shown) which can be electrically connected to the gate contact element 82.3 of the first power transistor chip 82 by means of an electrical conductive region of the adhesive paste 83.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

What is claimed is:

1. An electronic module, comprising:
a carrier;
a first semiconductor chip arranged on the carrier;
a second semiconductor chip arranged above the first semiconductor chip; and
a material layer adhering the second semiconductor chip to the carrier and encapsulating the first semiconductor chip.

2. The electronic module according to claim 1, wherein the material layer comprises a polymer.

3. The electronic module according to claim 1, wherein the material layer comprises an adhesive foil.

4. The electronic module according to claim 1, wherein the material layer comprises an adhesive paste.

5. The electronic module according to claim 1, wherein the second semiconductor chip is bigger than the first semiconductor chip.

6. The electronic module according to claim 1, wherein the first semiconductor chip has a thickness less than 100 μm.

7. The electronic module according to claim 1, wherein the second semiconductor chip has a thickness in a range from 40 μm to 800 μm.

8. The electronic module according to claim 1, wherein:
the first semiconductor chip comprises a power transistor chip; and
the second semiconductor chip comprises an integrated circuit chip.

9. The electronic module according to claim 1, wherein:
the first semiconductor chip comprises an integrated circuit chip; and
the second semiconductor chip comprises a power transistor chip.

10. The electronic module according to claim 1, wherein the material layer is electrically conductive.

11. The electronic module according to claim 10, wherein the material layer has an anisotropic electrical conductivity.

12. The electronic module according to claim 10, wherein the material layer has an isotropic electrical conductivity.

13. The electronic module according to claim 10, wherein:
the second semiconductor chip comprises an electrical contact element; and
the material layer electrically connects the electrical contact element of the second semiconductor chip with the carrier.

14. The electronic module according to claim 10, wherein:
the first and second semiconductor chips each comprise an electrical contact element; and
the material layer electrically connects the electrical contact element of the first semiconductor chip to the electrical contact element of the second semiconductor chip.

15. The electronic module according to claim 1, further comprising a third semiconductor chip arranged above the first semiconductor chip and besides the second semiconductor chip.

16. The electronic module according to claim 15, wherein the material layer adheres the third semiconductor chip to the carrier.

17. The electronic module according to claim 1, wherein:
the first semiconductor chip comprises a first electrical contact element on a first main face facing the second semiconductor chip, the electronic module further comprising an electrical member connecting the first electrical contact element with an electrical connector.

18. The electronic module according to claim 17, wherein the electrical connector is disposed in the same plane as the carrier.

19. An electronic module, comprising:
a first carrier;
a first semiconductor chip arranged on the first carrier;
a material layer encapsulating the first semiconductor chip; and
a second semiconductor chip arranged on the material layer.

20. The electronic module according to claim 19, further comprising:
a second carrier;
wherein the first semiconductor chip is also arranged on the second carrier; and
wherein the material layer covers the first and second carriers and the first semiconductor chip.

21. The electronic module according to claim 20, wherein the first semiconductor chip comprises a first electrical contact element connected with the first carrier and a second electrical contact element connected with the second carrier.

22. The electronic module according to claim 19, wherein the first semiconductor chip comprises an electrical contact element on a main face remote from the first carrier.

23. The electronic module according to claim 22, further comprising:
an electrical connector; and
an electrical member connecting the electrical contact element with the electrical connector.

24. The electronic module according to claim 23 wherein the electrical connector being disposed in a same plane as the first carrier.

25. A method for fabricating an electronic module, the method comprising:
attaching a first semiconductor chip to a first carrier;
forming a material layer on a main face of a second semiconductor chip; and
applying the second semiconductor chip to the first semiconductor chip so that the material layer is attached to the first carrier and encapsulates the first semiconductor chip.

26. The method according to claim 25, wherein the first semiconductor chip has a thickness less than 100 μm.

27. The method according to claim 25, wherein the material layer has a thickness greater than a thickness of the first semiconductor chip.

28. The method according to claim 25, wherein:
the material layer comprises an adhesive foil, and
forming the material layer comprises laminating the adhesive foil on the main face of the second semiconductor chip.

29. The method according to claim 25, wherein:
the material layer comprises an adhesive paste, and
forming the material layer comprises applying the adhesive paste on the main face of the second semiconductor chip.

30. The method according to claim 25, wherein the material layer comprises a polymer.
